(19) United States
(12) Patent Application Publication
(10) Pub. No.: US 2003/0006794 A1
(43) Pub. Date: Jan. 9, 2003

(54) Tape carrier package testing method

(76) Inventor: Hung-Tse Chiang, Hsinchu (TW)

Correspondence Address: J.C. Patents, Suite 250, 4 Venture, Irvine, CA, 92618, US

(21) Appl. No.: 10/188,392

(22) Filed: Jul. 1, 2002

Related U.S. Application Data
(63) Continuation-in-part of application No. 09/490,725, filed on Jan. 25, 2000, now abandoned.

(30) Foreign Application Priority Data
Jan. 10, 2000 (TW) 89100263

(51) Int. Cl. G01R 31/02

(52) U.S. Cl. 324/759

(57) ABSTRACT

A tape carrier package (TCP) testing method is performed by means of a TCP testing system that comprises a main test unit, a recorder and a hardware interface coupled with the main test unit and the recorder. Each tape carrier package is submitted to a first testing in the main test unit without being discarded regardless of the testing results provided by the main test unit. Each tape carrier package is attributed an identification code. The testing results obtained are recorded correspondingly to the identification codes through the hardware interface into the recorder. The recorded testing results are subsequently analyzed by an engineer and a re-testing is achieved to recover tape carrier packages initially tested defective. The packages that are tested defective in the second testing are discarded.

### CROSS-REFERENCE TO RELATED APPLICATION

This is a continuation in part of the U.S. patent application Ser. No. 09/490,725, filed on Jan. 25, 2000.

### BACKGROUND OF THE INVENTION

1. Field of the Invention

The present invention relates to semiconductor testing equipment. More particularly, the present invention relates to a package testing system and a package testing method that are more particularly suitable for testing of tape carrier packages.

2. Description of the Related Art

In the semiconductor fabrication, after the semiconductor packages have been completed, a testing operation is conventionally achieved to ensure the quality of the achieved semiconductor packages. FIG. 1 is a schematic drawing that illustrates a conventional tape carrier package (TCP) testing system. In FIG. 1, the tape carrier package (TCP) testing system includes a untested reel 10, a tested reel 20, a sample testing (DUT) unit 30, a punch head 40 and a belt conveyor 50.

In the above conventional TCP testing system, the TCP samples to be tested are mounted on the belt conveyor 50 by glue, soldering, or any adequate mounting means. The belt conveyor 50 with the samples to be tested is first wound around the untested reel 10. Then, the belt conveyor 50 conveys the TCP samples through the DUT unit 30 to execute a testing of the tape carrier packages. After the DUT unit 30, the TCP samples that are tested deficient are irreversibly discarded by means of the punch head 40 that punches the tested deficient tape carrier packages. The TCP samples which testing through the DUT unit 30 does not reveal any deficiency remain on the belt conveyor 50 and are wound around the tested reel 20. The deficient TCP samples are therefore removed from the belt conveyor 50 by means of the punch head 40.

FIG. 2 is a schematic drawing that illustrates a conventional mounting of the TCP samples on the belt conveyor. In FIG. 2, several samples, such as TCP samples 52, are regularly mounted on the belt conveyor belt 50. The samples 52 are conveyed to the DUT unit 30 by means of the conveyor belt 50. If the testing results of any sample 52 indicate a failure, this sample 52 is removed by the punch head 30 when the sample 52 reaches the location of the punch head 40.

However, it is known that a package testing system may be negatively affected by several factors such as the environmental conditions of testing. This may result in erroneous testing results from the DUT unit 30. Due to these erroneous testing results, acceptable TCP samples may be therefore irreversibly discarded by the punch head 40, which represents an undesirable loss that increases the fabrication cost.

### SUMMARY OF THE INVENTION

It is therefore an object of the invention to provide an integrated circuit package testing method and testing system that can prevent irreversible discards of packages which testing results have been distorted by environmental factors.

It is another object of the invention to provide an integrated circuit package testing method and a testing system implementing the same method, more particularly suitable for testing tape carrier packages, which record all the testing results of the tested packages.

To attain the above and other objectives, as embodied and broadly described herein, the invention provides an integrated circuit package testing system and testing method that are more particularly suitable for testing tape carrier packages. The testing system includes a main test unit, a recorder and a hardware interface coupled with the main test unit and the recorder. The main test unit tests the tape carrier packages and provides a plurality of corresponding testing results.

During a first testing, a plurality of tape carrier packages pass through the main test unit to be tested. No tape carrier package is discarded during this first testing. The state of the tape carrier packages that have passed through the main test unit during this first testing is therefore unchanged. Each of the tape carrier packages is further attributed an identification code. The testing results, provided by the first testing, are recorded correspondingly to the identification codes through the hardware interface into the recorder. Subsequently, an engineer analyzes the tape carrier packages and the corresponding testing results showing defects, and possible causes of erroneous testing results and reworkable packages are evaluated. The tape carrier packages with testing results exhibiting defects are subsequently submitted to a second testing, wherein the tape carrier packages that are tested defective in the second testing are discarded. Erroneous discards of good packages or discards of packages that may be recovered during the first testing are therefore prevented.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic drawing illustrating a conventional tape carrier package testing system;

FIG. 2 is a schematic drawing illustrating a conventional mounting of TCP samples on the belt conveyor; and

FIG. 3 is a schematic drawing illustrating a TCP testing system according to one preferred embodiment of the invention.

### DESCRIPTION OF THE PREFERRED EMBODIMENTS

FIG. 3 is a drawing schematically illustrating an intellectual TCP testing system, according to one preferred embodiment of the invention. In this embodiment, the testing system and the testing method of the invention are particularly suitable for testing, for example, tape carrier packages (TCP).

Considering the packaging process alone, the manufacturing cost of a tape carrier package is substantially high (about 30% of the total manufacturing cost of the final product). A tape carrier package typically comprises a tape carrier, usually formed from an insulating material of polyimide in which are included finely patterned conductor traces and leads, on which is mounted an integrated circuit (IC) chip. The tape carrier packages are implemented to principally package drive integrated circuit (IC) of thin film transistor (TFT) liquid crystal display (LCD). As TFT liquid crystal displays of higher resolution and larger size are developed, the number of pins of the TCP is increased while the pitch of the pins is reduced. For illustration, a current pin number of TCP for a 12.1-inch TFT liquid crystal display is 300, and it will be increased beyond 400 to about 500 for currently developed TFT liquid crystal displays. Meanwhile, the pitch of TCP is currently about 50 μm, and it will be reduced below about 40 μm in chip-on-film (COF) packages used in currently developed TFT LCD (COF packages have a two-layered film instead of conventionally three-layered film for TCP).

Due to the high number and the substantially fine pitch of the pins, it is difficult to perform an automatic testing of the TCP without errors, leading to erroneous discard of good packages or discard of packages that may be reworked. The origins of testing errors may be various and include, for example, the environmental conditions of the testing procedure. These erroneous discards of good packages or discards of packages that may be reworked can result in a loss that is not negligible, more particularly in the case of tape carrier packages having a high manufacturing cost. A principal aspect of the invention is therefore to provide a package testing method and a testing system implementing the same method that can overcome the above disadvantages by preventing the discard of good or reworkable packages.

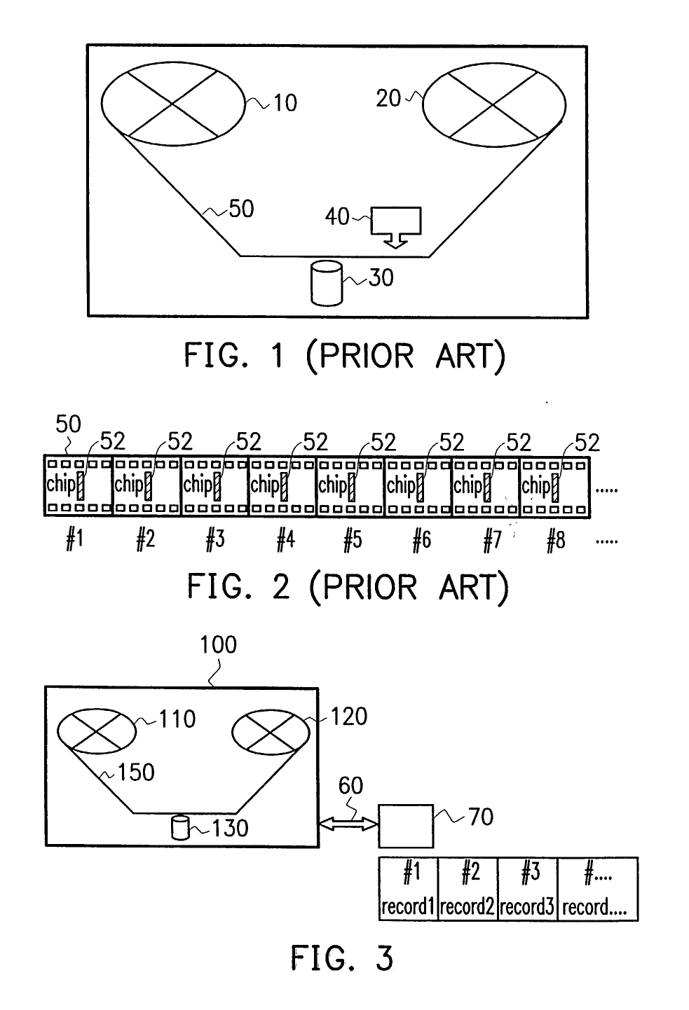

In FIG. 3, an automatic testing system of the invention suitable for testing, for example, TCP type packages, includes a main test unit 100, a hardware interface 60, and a recorder 70. The hardware interface 60 is coupled between the main test unit 100 and the recorder 70. The recorder can be, for example, a computer or a counter capable of recording the testing results of the TCP samples 52 provided by the main test unit 100. The main test unit 100 is similar to the conventional TCP testing system as shown in FIG. 1, but does not include the punch head 140 since the TCP samples are not definitely discarded in the main test unit 100. The TCP samples which testing results show defects will be discarded only after a second testing process confirms these defects.

The main test unit 100 includes an untested reel 110, a tested reel 120, a DUT unit 130, and a belt conveyor 150. Similar to the arrangement of FIG. 2, the TCP samples to be tested are mounted on the belt conveyor 150. The belt conveyor 150 conveys the TCP samples 52 from the untested reel 110 through the DUT 130 where the TCP samples 52 are tested. After the DUT 130, the belt conveyor 150 with the IC samples 52 is wound around the tested reel 120 without discarding of any TCP samples. The state of the TCP samples is therefore unchanged from the untested reel 110 through the DUT unit 130 to the tested reel 120.

Each of the TCP samples on the belt conveyor 150 is attributed an identification code, and the testing results of the TCP samples, provided by the DUT unit 130, are correspondingly stored with the identification codes through the hardware interface 60 in the recorder 70. The identification codes can be attributed by, for example, the hardware interface 60 or the recorder 70, or any means adapted to identify the IC samples. The attribution of the identification codes to the packages may be achieved, for example, during processing of the TCP samples within the main test unit 100. The testing procedure may include several items. Each item is represented by, for example, one bin. The testing results of each TCP sample therefore typically include several bins. Thereby, all the testing results are adequately recorded in the recorder 70.

After the above first testing is achieved in the main test unit 100, an engineer analyzes the recorded testing results that show defects. The origins of possible erroneous testing results and the causes of TCP defects can be subsequently evaluated from an analysis of these testing results through the expertise of the experienced engineer. The packages that may be reworked can be further subjected to a repair. In any cases, all the tape carrier packages having recorded testing results showing defects are submitted to a second testing that further should take into consideration the origins of testing errors discriminated by the analysis of the recorded testing results. This second testing may be a testing achieved through an automatic testing system. The TCP samples tested defective in this second testing then can be definitely discarded. With the testing method and testing system of the invention, the amount of discarded packages is therefore favorably reduced, which consequently reduces the fabrication cost.

In conclusion, the invention provides a TCP testing system and TCP testing method that test TCP type packages and further record all the corresponding testing results obtained without irreversibly discarding of any TCP samples having testing results showing defects. An engineer can analyze and retest the packages which testing results show deficiencies, the erroneous discards of good packages or discards of packages that may be reworked are thereby prevented.

It will be readily appreciated that the above embodiment with reference to TCP type packages should not be construed in a limited manner, and may encompass various types of semiconductor packages such as aforementioned COF packages also suitable with the invention. Those skilled in the art will therefore readily understand that various modifications and variations can be made to the structure of the present invention without departing from the scope or spirit of the invention. In view of the foregoing, it is therefore intended that the present invention cover modifications and variations of this invention provided they fall within the scope of the following claims and their equivalents.

What is claimed is:

1. A method of testing a tape carrier package (TCP), comprising:
providing a plurality of tape carrier packages;
attributing an identification code to each of the tape carrier packages;
performing a first testing of the tape carrier packages, wherein the first testing of the tape carrier packages provides a plurality of first testing results for each of the tape carrier packages;
recording the first testing results correspondingly to the identification codes;
analyzing the tape carrier packages and the correspondingly recorded testing results that show defects; and
performing a second testing of the tape carrier packages that have first testing results showing defects, and discarding the tape carrier packages tested defective in the second testing.

2. The method of claim 1, wherein the first testing results comprise a pass-or-failure information.

3. The method of claim 1, wherein the first testing results comprise an information indicating whether a tape carrier package has failed to the first testing.

4. The method of claim 1, wherein the first testing results are further analyzed to determine causes of erroneous first testing results.

5. The method of claim 1, further adapted to test chip-on-film (COF) type packages.

6. The method of claim 5, wherein the COF type packages include a plurality of pins having a pitch below about 40 μm.

7. The method of claim 1, wherein the tape carrier packages have a number of pins between about 400 and 500.
